(19) United States
(12) Patent Application Publication
(10) Pub. No.: US 2026/0290436 A1
(43) Pub. Date: Sep. 24, 2026

(54) CHANNEL-SHARED DATA STROBE

(71) Applicant: Rambus Inc., San Jose, CA (US)

(72) Inventor: Torsten Partsch, San Jose, CA (US)

(21) Appl. No.: 18/868,859

(22) PCT Filed: May 24, 2023
(86) PCT No.: PCT/US2023/023432

§ 371 Date: Nov. 25, 2024

Related U.S. Application Data
(60) Provisional application No. 63/347,631, filed on Jun. 1, 2022.

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

A shared data strobe signal is applied to time data reception simultaneously in two or more transactionally-independent memory channels, lowering strobe signaling overhead by at least half relative to conventional strobe-per-channel solutions.

### TECHNICAL FIELD

The disclosure herein relates to synchronous memory components and systems.

### DRAWINGS

The various embodiments disclosed herein are illustrated by way of example, and not by way of limitation, in the figures of the accompanying drawings and in which like reference numerals refer to similar elements and in which:

FIG. 1 illustrates an embodiment of a strobe-sharing dual-channel memory system having a dual-channel dynamic random access memory (DRAM) component and a dual-channel memory control component;

FIG. 2 illustrates an exemplary sequence of memory read operations within the shared-strobe memory system of FIG. 1;

FIG. 3 illustrates an exemplary shared data strobe transmission from control component to memory component in connection with overlapping channel A and channel B column write requests;

FIG. 4 illustrates another shared data strobe example, in this case with temporally offset sequences of column read transactions for both the A and B memory channels;

FIG. 5 illustrates exemplary shared-strobe conflict resolution implemented scheduling circuitry within the control component of FIG. 1—reordering and re-timing column access commands to ensure same-direction transmission of any concurrent data bursts on the A and B memory channels;

FIG. 6 illustrates a more detailed embodiment of a shared-strobe DRAM component explicitly showing the channel A and channel B command/address interfaces and command-execution state machines for the A and B memory channels;

FIG. 7 illustrates an alternative shared-strobe, multi-channel memory component in which distinct A and B memory channels are implemented in counterpart package-integrated DRAM dies; and

FIG. 8 illustrates an exemplary implementation of a data PHY (physical signaling interface) controller, data-strobe controller, data PHY, strobe PHY and at least part of a strobe input/output interface that may instantiate like-named components within the FIG. 7 DRAM dies.

### DETAILED DESCRIPTION

In various embodiments herein, a shared data strobe signal is applied to time data reception simultaneously in two or more transactionally-independent memory channels, lowering strobe overhead by at least half relative to conventional strobe-per-channel solutions. In a number of embodiments, a single integrated-circuit memory die is implemented with multiple memory channels having respective/distinct command interfaces and memory cores to enable concurrent execution of independent, channel-specific streams of memory read and write commands. Corresponding channel-specific streams of read data and write data are transmitted/received by respective channel-specific sets of on-die data transceivers with synchronous operation of those transceivers timed by a channel-shared data strobe signal instead of conventional per-channel strobe signals. Through this approach, relatively narrow per-channel data interfaces may be implemented (e.g., x2 (two data lines) or even x1 (single data line)) without the outsized strobe line overhead otherwise required, particularly where single-ended data signaling (one data line per data signal) is timed by a differential strobe (two strobe lines per strobe signal). In other embodiments, a similar strobe overhead reduction is implemented within a multi-die integrated circuit package where a strobe signal received via one die is conveyed to and applied to time data signal reception within one or more of the other dies. These and other features and embodiments are discussed in greater detail below.

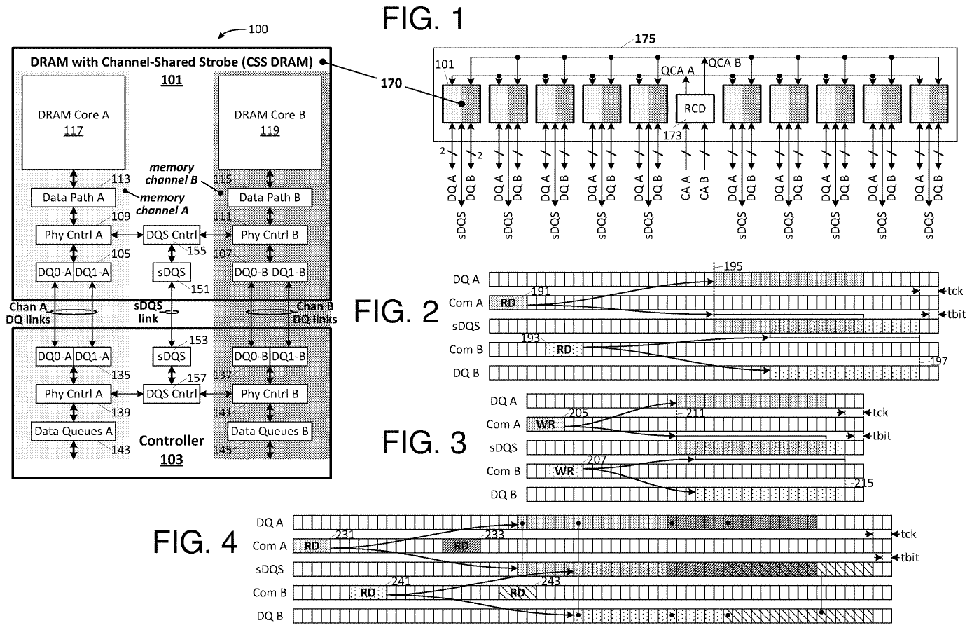

FIG. 1 illustrates an embodiment of a strobe-sharing dual-channel memory system 100 having a dual-channel dynamic random access memory (DRAM) component 101 and a dual-channel memory control component 103 (“controller”). Each of the two memory channels, ‘A’ and ‘B’, within DRAM component 101 includes a respective synchronous data interface (105, 107), physical interface control circuitry (109,111), data path circuitry (113, 115), DRAM core (117, 119) and command/address interface (the latter not specifically shown)—an arrangement that enables independent memory accesses to be transacted within each of the two channels (e.g., two different command/address streams directed to and executed within the different/independent same-die memory channels A and B). Memory control component 103 (“controller”) likewise includes per-channel command/address queues (not specifically shown) to supply separate streams of command/address values for the A and B memory channels, as well as channel-dedicated synchronous data interfaces 135, 137, physical interface controllers 139, 141, and read/write data queues 143, 145.

In the FIG. 1 embodiment, synchronous and bidirectional data interfaces (DQ) are implemented within both the DRAM and control components (105/107 and 135/137) with relatively narrow 2-bit (x2) widths (i.e., supporting two bidirectional single-ended data links per channel) with data reception within the destination component (DRAM 101 for write data, controller 103 for read data) timed by a data strobe signal transmitted by the data-sourcing component concurrently with the read or write data burst. Rather than requiring a conventional per-channel data strobe, however, the two memory channels share a single differential data strobe (sDQS)—an approach that halves the strobe signaling overhead (contacts in the controller and DRAM dies, chip-to-chip conductors/traces, strobe reception/transmission circuitry, etc.) and thus avoids the otherwise onerous strobe-to-data line ratio incurred in narrow-width data interfaces (i.e., one-to-one in a x2 data interface with per-channel differential strobe as two strobe lines, DQS+and DQS−, are required for every two DQ lines). As shown, the channel-shared strobe link (“sDQS link”) is coupled between memory-side and controller-side strobe interfaces 151, 153 which are coupled, in turn, to respective strobe controller circuits, 155, 157. As discussed below, the strobe controllers convey a shared incoming strobe signal (a write data strobe inbound to the DRAM component and a read data strobe inbound to the controller component) to the physical signaling controllers for both memory channels, timing data reception for both memory channels with a single channel-shared strobe.

Referring to view 170 of Figure-1, dual-channel DRAM component 101 may be mounted, along with multiple other identical DRAM components and a dual-channel registered clock driver 173 (RCD), to the face of a memory module 175 (e.g., with two in-line rows of such DRAM components being implemented on respective faces of the module substrate to form a dual inline memory module or DIMM) having per-DRAM data contacts (two channel A data contacts and two channel B data contacts per memory component), a per-DRAM channel-shared data strobe contact (sDQS) and respective command/address contacts for the A and B memory channels. Though not specifically shown, incoming chip-select and/or chip-ID signals are supplied to RCD 173 which in turn enables a specified one of multiple ranks of memory dies (i.e., a subset of the memory dies hosted on memory module 175, with each rank-constituent memory die coupled to a respective set of the module DQ links) to respond to an incoming command. More specifically, in the case of command/address values (CA) arriving via the RCD command/address interface for channel A (i.e., “CA A”), RCD 173 issues corresponding on-module command/address values (QCA A) to the channel A command/address interface within the module-mounted memory components with the corresponding RCD-issued chip-select/chip-ID signals enabling a specific memory rank (i.e., subset of module mounted DRAM components 101) to respond to those commands—transmitting or receiving data via their respective data interfaces in the case of memory read/write commands, with data receive sampling timed by a strobe signal conveyed on the channel-shared strobe line coupled to a given memory component within the selected rank. Ditto for command/address values arriving via the RCD command/address interface for channel B—RCD 173 issues corresponding on-module command/address values (QCA B) to the channel B interfaces within the memory components (again, with a selected rank enabled to respond to those command/address values, transmitting or receiving data via their respective data interfaces in the case of memory read/write commands).

While strobe-sharing DRAM components are shown in (and described with respect to) FIG. 1 and other embodiments herein, integrated-circuit memory components implemented with various memory technologies instead of or in addition to DRAM may be deployed in all such embodiments, including, for example and without limitation, static random access memory (SRAM), magnetoresistive random access memory (MRAM), resistive random access memory (RRAM), Flash memory, conductive bridging random access memory (CBRAM), etc. Also two or more strobe-sharing integrated-circuit memory dies may be co-packaged side-by-side or stacked on top of one another.

FIG. 2 illustrates an exemplary sequence of memory read operations within the shared-strobe memory system of FIG. 1 and more specifically DRAM “column reads” as a column-address-specified column of data is retrieved from a page buffer within the subject DRAM component (following transfer of that data page from a row-address-selected row of storage cells within a bank-address-selected bank of storage cells in a row-command-triggered activation operation). As shown, a column read command (RD) directed to memory channel A is received within the channel-A command/address interface (“Com A”) of a given DRAM component at 191—for example, a packetized column command and address received/sampled over a two clock cycle interval (2*tck, where tck is the period of a clock supplied to on-module memory components and ‘*’ denotes multiplication) corresponding to four successive data bit intervals (tbit—also referred to as a unit interval) in this double-data-rate example (i.e., tbit=tck/2). Three clock cycles later, another column read command 193 directed to memory channel B is received within the channel B command/address interface (“Com B”) of the DRAM component. The DRAM component executes the memory read commands independently within the A and B memory channels, in each case transmitting the read data back to the control component, together with a channel-shared data strobe signal, after a predetermined column-read latency transpires. More specifically, the DRAM component begins transmitting the shared data strobe signal (i.e., the active edges of the shared data strobe) concurrently with commencement of the channel A read data burst at 195, continuously transmitting the shared strobe signal until the conclusion of the channel B read data burst at 197 (strobe preamble and postamble not shown). Accordingly, the shared data strobe transmission continuously spans both the initial part of the channel A read data burst (shaded to match the channel A read data request), the overlapping portion of the channel A and channel B read data bursts (shaded per channel A column read request and hashed per column B column read request), and then the final portion of the channel B read data burst that extends beyond the conclusion of the channel A read data burst (unshaded and hashed per channel B column read request).

FIG. 3 illustrates an exemplary shared data strobe transmission from control component to memory component in connection with overlapping (but temporally offset) channel A and channel B column write requests (205, 207). As shown, the shared data strobe commences (i.e., active strobe edges commencing) with the start of a channel A write data burst at 211 and continues through the end of a channel B write data burst at 215—spanning a net interval longer than either of the channel A or channel B write data bursts alone with that total interval established by the write data burst length plus the offset between the channel A and channel B data burst starting times (and thus the offset between the channel A and channel B column write requests which, in the FIG. 3 example, is one clock cycle (1*tck)). Though not specifically shown in FIG. 3, strobe preamble and postamble waveforms (preceding and succeeding active strobe edges) are generally conveyed between controller and memory components in the various embodiments presented herein.

FIG. 4 illustrates another shared data strobe example, in this case with temporally offset sequences of column read transactions for both the A and B memory channels—back-to-back column reads via memory channel A (231, 233) and back-to-back column reads in memory channel B (241, 243), with the latter (channel B read requests) commencing three clock cycles latter than the former. As shown, the shared data strobe signal commences with the initial channel A read data burst (lightly shaded) and continues without interruption until the conclusion of the final channel B read data burst and thus spans a continuous interval longer than the collective duration of back-to-back read data bursts on either memory channel alone (i.e., an interval of n*t_{burst}+L, where ‘n’ is the largest number of back-to-back reads on either channel, t_{burst} is the data burst interval for a given column read, and ‘L’ is the temporal offset between commencement of the initial channel A and channel B read data bursts—applicable so long as the longest of the collective channel A and B read data bursts does not completely hide the read data burst on the other channel. As shown, the shared data strobe is initially applied to time read data reception (within the memory control component) for the channel A read data burst only, followed by shared-strobe (sDQS) timing of read data reception for both the initial column read transactions on both the A and B channels (shaded and hashed to match the initial channel A and channel B column read commands), followed after conclusion of the initial channel A read data burst and commencement of the ensuing channel A read data burst (more darkly shaded) by sDQS timing of read data reception for both the initial column read transaction on memory channel B and the trailing column read transaction on memory channel B, and then by read data reception timing of the latter-transaction data bursts for both channels A and B and then finally by timing read data reception for the latter channel B data burst alone.

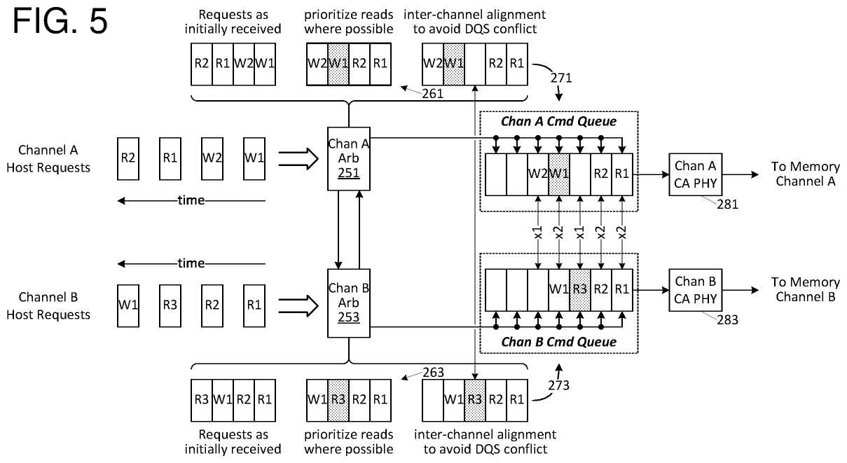

In the FIG. 1 embodiment, the shared data-strobe line may convey a data strobe in only one direction at a time and thus inhibits simultaneous data transmissions in opposite directions on the A and B memory channels—imposing temporal constraints on transaction timing for the A and B memory channels to avoid resource contention/conflict. In a number of embodiments, scheduling circuitry within control component 103 resolves any possible conflicts by reordering and occasionally re-timing column access commands within the channel A and/or channel B command queues (not specifically shown) and data queues 143 and 145 to ensure same-direction transmission of any concurrent data bursts on the A and B memory channels. FIG. 5 illustrates such operation in the context of exemplary sequences of host requests (e.g., from one or more CPUs or other transaction requestors) issued to the A and B memory channels. In the depicted example, a command arbiter 251 for channel A receives a sequence of write commands (W1 then W2) followed by a sequence of read commands (R1 then R2) over the same interval in which a command arbiter 253 for memory channel B receives a sequence of read commands (R1, R2, R3) followed by a write command W1. If issued concurrently in the order received, the channel-A write commands and initial channel-B read commands (R1, R2) would yield a conflict with respect to the shared strobe line. In this case, channel A arbiter 251 avoids this contention by prioritizing the channel-A read commands ahead of the channel A write commands—an operation carried out in any case where not constrained by coherency/data-dependency concerns to enable read data delivery as promptly as possible. As shown, in the revised (after prioritizing reads ahead of writes) command sequences at 261 and 263, a potential shared-strobe conflict remains with respect to the final channel-B memory read command (R3) and the initial channel-A write command (W1)—commands shaded for emphasis in sequences 261, 263. To resolve this conflict, channel A arbiter 251 (the arbiter having the lower priority of the otherwise contending/conflicting write and read commands) inserts a delay interval (or timing bubble) into the channel-A command queue to delay issuance of the initial memory write command (and all ensuing commands) by an interval sufficient to avoid the shared data strobe conflict—e.g., delay write data transmission until at least the bit interval following reception of the final bit of the R3 read data burst. The final command queue arrangement is depicted conceptually at 271 and 273, showing the channel-B commands queued as originally received, with the channel A commands reordered (reads ahead of writes) and delayed (bubble between R2 and W1) to avoid shared-strobe conflict. Counterpart commands within the two command queues are marked by “x2” where the shared strobe will be applied bilaterally (jointly) to time data reception in the A and B memory channels (within the controller or memory component as the case may be) and by “x1” wherein the shared strobe will be applied unilaterally to time data reception exclusively for one channel or the other. While the command queues are depicted conceptually as first-in-first-out (FIFO) buffers (e.g., through which command/address values are shifted), in actual implementation, arbiters 251 and 253 may effect such FIFO operation through pointer manipulation (e.g., dynamically selecting which of a set of command/address storage elements is next to drive the Channel A CA PHY 281/channel B CA PHY 283)

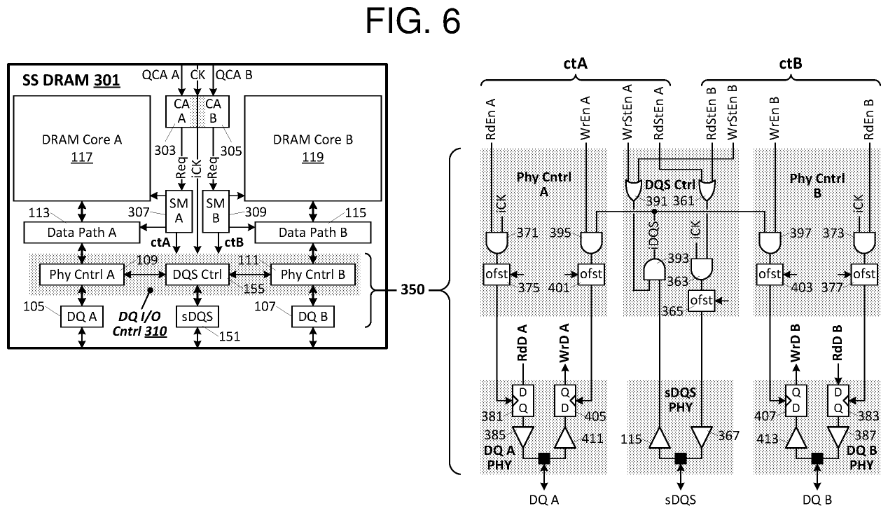

FIG. 6 illustrates a more detailed embodiment of a shared-strobe DRAM component 301 explicitly showing the channel A and channel B command/address interfaces 303 and 305 (various other control signals may be received within DRAM 301 and in some cases shared between channels—e.g., clock enable) and command-execution state machines 307 and 309 (or sequencers, command decoders, etc.) for the A and B memory channels. As shown, a shared portion of the channel command/address interfaces 303, 305 (shown conceptually by gray shading) generates, in response to incoming clock signal CK, an internal clock signal (iCK) that is supplied to shared-strobe controller 155 and the data PHY controllers 109 and 111 for the A and B memory channels—circuitry collectively referred to herein as a data input/output (IO) controller 310. The internal clock signal may, in frequency-divided form or otherwise, be supplied also to the channel A and B state machines (307, 309) and other circuit blocks within the memory component to enable clock-synchronized operations.

Referring to detail view 350 of the data I/O controller, channel A and B data interfaces (105, 107) and shared data strobe interface 151, the channel A and channel B state machines output (in response to incoming column read and column write commands) read and write enable signals and read-strobe and write-strobe enable signals to selectively enable shared-strobe data I/O for the A and B memory channels. More specifically, the channel A state machine asserts (i) a read-enable (RdEn A) and read-strobe enable (RdStEn A) to the channel A physical interface controller (“PHY Cntrl A”) and shared DQS controller (“DQS Cntrl”), respectively, in response to channel A column-read requests, and (ii) a write-enable (WrEn A) and write-strobe enable (WrStEn A) to the channel-A PHY controller and shared DQS controller, respectively, in response to channel A column-write requests—control signals collectively shown as “ctA.” The channel B state machine likewise asserts RdEn B/RdStEn B and WrEn B/WrStEn B to the channel-B PHY controller (“PHY Cntrl B”) and shared DQS controller (i.e., “ctB”) in response to channel-B column-read and column-write commands.

Still referring to detail view 350, read-strobe enable assertion for either or both memory channels drives the output of OR gate 361 high within the DQS controller, enabling iCK (internal clock) to propagate through AND gate 363 and offset-delay element 365 to be output (via output driver 367 within sDQS PHY) as the outbound read data strobe. Read enable assertion for memory channel A and/or memory channel B (i.e., RdEnA and/or RdEnB) likewise enables iCK propagation (via AND gate 371 or 373 and then offset-delay element 375 or 377) to the timing input of output flop stage 381 or 383 within the channel A or channel B data PHY, thus enabling read data for the corresponding channel (RdD A and/or RdD B) to be clocked into the output flop stage for transmission to the controller component, synchronously with the read data strobe, via output driver 385 and/or 387. Offset delay elements 365, 377 and 375 are programmed (e.g., establishing a digital delay setting corresponding to a desired temporal delay) during initial and possibly occasional/periodic training operations to align data and strobe transmissions to achieve desired controller-side signal arrival. In alternative embodiments, one or more of the offset delay elements may be omitted in favor of controller-side sample-time alignment circuitry.

Write-strobe enable assertion for either memory channel (WrStEn A and/or WrStEn B) drives the output of OR gate 391 high which, in turn, enables an incoming shared data strobe signal (i.e., arriving with incoming write data) to propagate through AND gate 393 and thereby deliver an internal data strobe signal (iDQS) to the inputs of AND gates 395 and 397 within the channel A and channel B PHY controllers. Those AND gates, when enabled by assertion of the write-enable signal for the corresponding memory channel (WrEn A and/or WrEn B), pass the internal data strobe signal through an offset delay element (401, 403) to the timing input of input flop stage 405 or 407, sampling the incoming data signal (conditioned within amplifier/buffer 411, 413) to yield a digital write data stream for the subject memory channel (WrD A or WrD B). Accordingly, when both memory channels receive write data concurrently (e.g., simultaneous or at least overlapping incoming write data bursts), the internal data strobe is applied to jointly (bilaterally) sample respective data streams for the A and B memory channels. Where write data is received within one channel only (e.g., during an initial or trailing portion of a write data burst where the write data stream in one channel leads or lags the other, or during an interval in which one memory channel is idle), only the active-channel write enable (WrEn A or WrEn B) will be asserted, so that data will be strobed unilaterally into the write data register (405 or 407) for only that active channel.

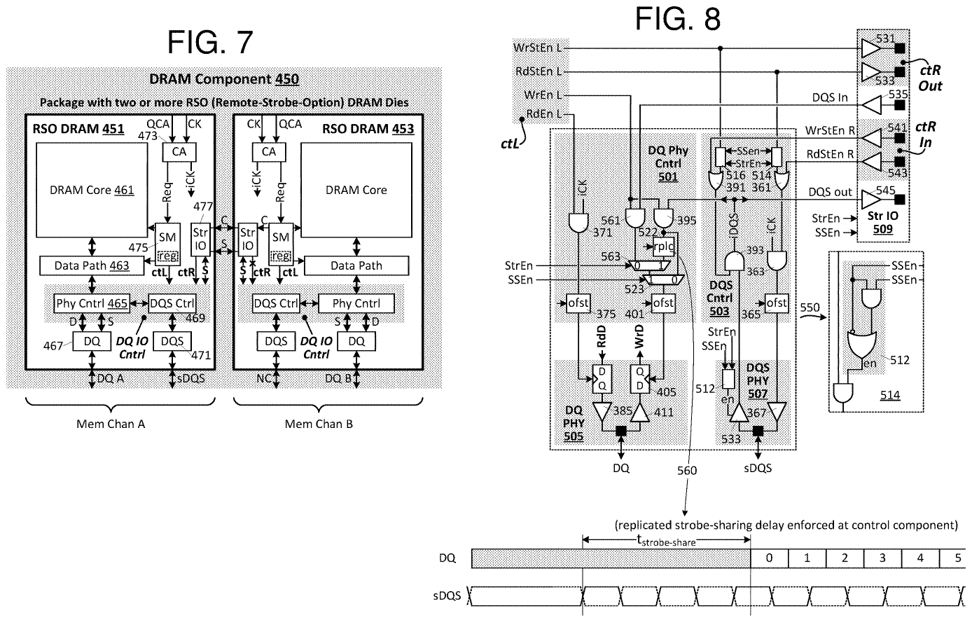

FIG. 7 illustrates an alternative shared-strobe, multi-channel memory component 450 in which distinct A and B memory channels are implemented in counterpart package-integrated DRAM dies 451, 453 each capable of optionally (according to programmed configuration) receiving/transmitting data with respect to a strobe received from/transmitted by the other die and thus referred to as a remote-strobe-option (RSO) DRAM die. In the depicted example, each RSO DRAM die (451 and 453) includes a DRAM core 461, data path circuitry 463, data PHY controller 465, data PHY 467, strobe PHY controller 469, strobe PHY 471, command/address interface 473 and state machine 475 that operate generally as described in reference to FIGS. 1 and 6. As shown, the physical data strobe interface is enabled (and connected to exterior wiring within IC package 455) for only one the two DRAM dies—the channel A DRAM die 451 being the strobe-enabled die in this example—and passed through a strobe IO interface 477 to the counterpart strobe PHY controller for the other DRAM die 453 (the “auxiliary-strobe” die). More specifically, where a memory read or write is commanded within the channel B memory die (453), the strobe I/O circuit within that die coordinates with the strobe I/O circuit (477) for the channel A DRAM die 451 (issuing control signals (‘C’) to notify the DQS PHY controller 469 within die 451 of an impending read data burst transmission or write data burst reception. Where the strobe I/O control signals indicate a channel-B read data transmission, the DQS PHY controller 469 for the channel A memory die responds by enabling data strobe transmission via the channel A strobe PHY 471—outputting a strobe signal from the channel A DRAM die to the memory control component to enable strobe-timed reception (within the memory control component) of read data transmitted by the channel B memory die. Where the strobe I/O control signals indicate channel-B write data reception, the channel A DQS PHY controller 469 receives the incoming data strobe and routes the strobe via the counterpart strobe I/O circuits 477 to the channel B PHY controller where the strobe is applied to time reception of the incoming write data. In the FIG. 7 embodiment, the DRAM dies 451, 453 include respective configuration registers (i.e., “reg” elements within state machines 475, as an example) that are programmed to establish the operating mode of the DRAM dies as either strobe-sharing or strobe-independent, and if the former (shared-strobe) as either the strobe-enabled die or the auxiliary strobe die (strobe-disabled die).

FIG. 8 illustrates an exemplary implementation of a PHY controller 501, DQS controller 503, data PHY 505, strobe PHY 507 and strobe I/O interface 509 that may instantiate like-named components within each of the RSO DRAM dies shown in FIG. 7. In the depicted example, each of the dies (only one of which is shown) may be configured (e.g., by programming the configuration register “reg” shown in FIG. 7) for strobe-sharing operation (SSen=1) or strobe-independent operation (SSen=0) and, if strobe-sharing is enabled, as either the strobe-enabled die (StrEn=1) or the strobe-disabled die (StrEn=0). When configured for strobe-independent operation (no strobe-sharing), the logic-low SSen signal (i) disables strobe signal reception/transmission and control signal reception/transmission within strobe I/O interface 509, (ii) enables, via operation of enable logic 512, read strobe reception within signal receiver 533, (iii) enables read strobe enable and write strobe enable signals (two of the local control signals, ctL, from local state machine 477 of FIG. 7) to pass through respective gating circuits 514, 516 to logic OR gates 361 and 391 and thereby enable read data strobe transmission and write data strobe distribution generally as discussed in reference to FIG. 6, and (iv) enables iDQS (the internal write data strobe propagating through AND gate 395 when WrEn L is asserted) to bypass replica delay element 522—provided to account for strobe-sharing delay as discussed below—via multiplexer 523 to time inbound write data sampling as discussed in reference to FIG. 6.

When counterpart RSO DRAM dies are configured for strobe-sharing operation (SSen=1), control-signal drivers 531 and 533 and write-strobe receiver 535 receiver within strobe I/O interface 509 of the strobe-disabled one of those dies (StrEn=0) are enabled to transmit locally-generated read and write strobe enable signals (RdStEn L and WrStEn L) to the counterpart strobe-enabled die (StrEn=1) and to receive an inbound write strobe signal (DQS In) from the strobe-enabled die. Control signal receivers 541, 543 and write strobe driver 545 are correspondingly enabled within the strobe-enabled die to receive inbound remote strobe-enable signals (WrStEn R, RdStEn R) and to output a locally received write data strobe to the strobe-disabled die (i.e., DQS Out). Though not specifically shown (because only one of the two RSO dies is shown), drivers 531, 533 and receiver 535 within the strobe-disabled die are coupled via chip-to-chip signaling conductors to receivers 541, 543 and driver 545, respectively, within the strobe-enabled die. Control signal drivers 531, 533 and strobe signal receiver 535 are disabled within the strobe-enabled die while corresponding control signal receivers 541, 543 and strobe signal driver 545 are disabled within the strobe-disabled die. Accordingly, chip-to-chip connections between signal drivers 531, 533 and receiver 535 within the strobe-enabled die and signal receivers 541, 543 and driver 545 within the strobe-disabled die are optional, though when present, enable either of the RSO DRAM dies to be programmed as the strobe-enabled die and the other as the strobe-disabled die.

When operating in strobe-sharing configuration (SSen=1), the local and remote strobe-enable signals (RdStEn L, WrStEn L, RdStEn R, WrStEn R) within the strobe-enabled die serve essentially the same roles with respect to strobe signal transmission and reception as the channel-A and channel-B strobe-enable signals shown in FIG. 6. More specifically, local and remote read-strobe enable signals (the former propagating through gating circuit 514—implemented, for example, as shown in detail view 550) are ORed in logic gate 361 to enable shared data strobe transmission via DQS PHY 107 generally as discussed in reference to FIG. 6. Similarly, local and remote write-strobe enable signals (the former passing through gating circuit 516 which may be implemented identically to circuit 514) are ORed in logic gate 391 to enable distribution of internal DQS signal (iDQS) generally as discussed above (with respect to FIG. 6), with iDQS additionally being transmitted to the remote (strobe-disabled) die via driver 545 (and received therein via counterpart receiver 535).

In a number of embodiments, the host control component (e.g., controller 103 of FIG. 1) is additionally programmed to enabled shared-strobe operation across multiple RSO DRAM dies or, alternatively, to operate those dies independently (issuing separate strobe signals to each rather than a shared strobe signal to only one RSO DRAM die). When programmed for strobe-sharing operation, the control component enforces a timing offset between write strobe transmission and write data transmission—transmitting the write strobe and then enforcing a strobe-sharing delay (t_{strobe-share} as shown for example at 560) before transmitting the corresponding write data with that strobe-sharing delay corresponding (by virtue of initial and possibly ongoing timing calibration operations) to the time required for a write strobe signal received via the strobe-enabled die to propagate through the counterpart strobe I/O interfaces 509 to the DQ PHY 505 of the strobe-disabled die. By this operation, edges of the write strobe signal inbound within the strobe-disabled die (i.e., transitions of the DQS In signal received via receiver 535 and propagating via locally-enabled AND gate 561, multiplexers 563 and 623 and optional delay element 401) arrive at the triggering input of sampling circuit 405 in a desired phase relationship with the write data signal arriving via signal receiver 411 (e.g., active edges of write strobe aligned with midpoints of successive write data eyes).

In a number of embodiments, the control component imposes the strobe-to-write data offset shown at 560 (i.e., write data delayed by t_{strobe-share}) in write operations directed concurrently to the strobe-enabled and strobe-disabled dies (bilateral strobe-shared write operations) as well as write operations directed exclusively/unilaterally to the strobe-enabled die. Accordingly, to account for the early arrival of the write strobe within the strobe-sharing/strobe-enabled die (i.e., write strobe arriving t_{strobe-share} sooner than the write data), iDQS is routed, via operation of multiplexers 563 and 523, through replica delay element 522, delaying propagation of iDQS to sampling circuit 405 by t_{strobe-share} and thus achieving the desired strobe/data alignment within the strobe-enabled die.

In alternative embodiments, the control component may selectively impose the t_{strobe-share} delay to reduce latency in write operations directed exclusively to the strobe-enabled die (i.e., no overlapping write data transmission to the strobe-enabled and strobe-disabled dies). In one implementation, for example, the control component, in response to detecting an interval in which write data is to be transmitted unilaterally to the strobe-enabled component (no write data transmission to strobe-disabled die), issues a specialized “low-latency” write command to the strobe-enabled die to indicate that the replica delay is to be bypassed within DQ PHY controller 501, transmitting write data and write strobe in a timing relationship nominally identical to that in the strobe-disabled DRAM die configuration. The strobe-enabled DRAM die responds to the low-latency write command by gating the SSen input to multiplexer 523 for the duration of the write data burst, bypassing replica delay element 522 to enable strobe-timed write data reception at an earlier point in time (less latency) than during bilateral write data transmission (i.e., concurrent write data transmission to both the strobe-enabled and strobe-disabled dies). During bilateral write data transmission (one or more edges of shared strobe signal applied to time write data sampling in both RSO DRAM dies), the control component issues identical write commands—neither being a low-latency write command—to both DRAM dies (though with optional time stagger as discussed above and arbitrarily different address values) so that the strobe-enabled DRAM die enforces the replica delay as discussed above.

The various systems, integrated-circuit components, circuit architectures, circuit operations, calibration operations etc. disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit, layout, and architectural expressions may be implemented include, but are not limited to, formats supporting behavioral languages such as C, Verilog, and VHDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, computer storage media in various forms (e.g., optical, magnetic or semiconductor storage media, whether independently distributed in that manner, or stored “in situ” in an operating system).

When received within a computer system via one or more computer-readable media, such data and/or instruction-based expressions of the above described circuits and device architectures can be processed by a processing entity (e.g., one or more processors) within the computer system in conjunction with execution of one or more other computer programs including, without limitation, net-list generation programs, place and route programs and the like, to generate a representation or image of a physical manifestation of such circuits and architectures. Such representation or image can thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the disclosed embodiments. In some instances, the terminology and symbols may imply details not required to practice those embodiments. For example, any of the specific quantities/types of signal polarities, bit-depths, interface widths, memory-channel quantities, die-per-package quantities, and the like can be different from those described above in alternative embodiments. Signal paths depicted or described as individual signal lines may instead be implemented by multi-conductor signal buses and vice-versa and may include multiple conductors per conveyed signal (e.g., differential or pseudo-differential signaling). The term “coupled” is used herein to express a direct connection as well as a connection through one or more intervening functional components or structures. Programming of operational parameters (e.g., strobe-sharing enabled, strobed vs. auxiliary die, etc.) or any other configurable parameters may be achieved, for example and without limitation, by loading a control value into a configuration register, mode register or other storage circuit within above-described integrated circuit devices in response to a host instruction and/or on-board processor or controller (and thus controlling an operational aspect of the device and/or establishing a device configuration) or through a one-time programming operation (e.g., blowing fuses within a configuration circuit during device production), and/or connecting one or more selected pins or other contact structures of the device to reference voltage lines both inside the package (e.g., on the substate or outside the integrated circuit package as where an IC contact is coupled to a printed circuit board trace—also referred to as strapping) to establish a particular device configuration or operation aspect of the device. The terms “exemplary” and “embodiment” are used to express an example, not a preference or requirement. Also, the terms “may” and “can” are used interchangeably to denote optional (permissible) subject matter. The absence of either term should not be construed as meaning that a given feature or technique is required.

Various modifications and changes can be made to the embodiments presented herein without departing from the broader spirit and scope of the disclosure. For example, features or aspects of any of the embodiments can be applied in combination with any other of the embodiments or in place of counterpart features or aspects thereof. Accordingly, the specification and drawings are to be regarded in an illustrative rather than a restrictive sense.

1. An integrated-circuit memory component comprising:
first and second data interfaces;
first and second command/address interfaces to receive respective first and second memory access commands, the first memory access command indicating that a first write data burst is to be received via the first data interface and the second memory access command indicating that a second write data burst is to be received via the second data interface;
a shared data strobe interface to receive a first data strobe signal; and
control circuitry to:
enable the first write data burst to be sampled within the first data interface at times indicated by the first data strobe signal, and
enable the second write data burst to be sampled within the second data interface at times indicated by the first data strobe signal.

2. The integrated-circuit memory component of claim 1 wherein the first and second command/address interfaces to receive the respective first and second memory access commands at respective times that are offset from one another by a first interval and wherein the control circuitry to enable the first and second write data bursts to be sampled within the first and second data interfaces comprises circuitry to enable the first and second write data bursts to be sampled over respective second and third intervals that are offset from one another by the first interval.

3. The integrated-circuit memory component of claim 1 wherein first and second command/address interfaces and first and second data interfaces are disposed on a first integrated circuit die that forms at least part of the integrated-circuit memory component.

4. The integrated-circuit memory component of claim 1 wherein the control circuitry to enable the first write data burst to be sampled at times indicated by the first data strobe signal comprises circuitry to (i) generate a first delayed data strobe signal having a first calibrated phase offset from the first data strobe signal and (ii) enable the first write data burst to be sampled in response to transitions of the first delayed data strobe signal.

5. The integrated-circuit memory component of claim 4 wherein the circuitry to enable the first write data burst to be sampled in response to transitions of the first delayed data strobe signal comprises circuitry to enable the first write data burst to be sampled twice in succession for each cycle of the first delayed data strobe signal.

6. The integrated-circuit memory component of claim 4 wherein the control circuitry to enable the second write data burst to be sampled at times indicated by the second data strobe signal comprises circuitry to (i) generate a second delayed data strobe signal having a second calibrated phase offset from the first data strobe signal and (ii) enable the second write data burst to be sampled in response to transitions of the second delayed data strobe signal.

7. The integrated-circuit memory component of claim 1 wherein the first data strobe signal comprises a plurality of active transitions that are preceded by a strobe preamble and succeeded by a strobe postamble, the active transitions continuing throughout an interval that exceeds a duration of the first write data burst and exceeds a duration of the second write data burst.

8. The integrated-circuit memory component of claim 1 wherein the first data strobe signal comprises active transitions that are preceded by a strobe preamble and succeeded by a strobe postamble, and wherein a first subset of the active edges indicates times at which an initial portion of first write data burst is to be sampled and a second subset of the active edges indicates times at which a trailing portion of the second write data burst is to be sampled, the first subset including at least one active edge not included in the second subset and vice-versa.

9. The integrated-circuit memory component of claim 1 wherein the first command/address interface, the first data interface and shared data strobe interface are implemented in a first integrated circuit die within the integrated-circuit memory component and the second command/address interface and the second data interface are implemented in a second integrated circuit die within the integrated-circuit memory component and wherein the control circuitry to enable the second write data burst to be sampled within the second data interface at times indicated by the first data strobe signal comprises circuitry to convey the first data strobe signal from the first integrated circuit die to the second integrated circuit die.

10. The integrated-circuit memory component of claim 1 wherein the first and second command/address interfaces comprise circuitry to receive respective third and fourth memory access commands, the third memory access command indicating that a first read data burst is to be transmitted to a memory control component via the first data interface and the fourth memory access command indicating that a second read data burst is to be transmitted to the memory control component via the second data interface, and wherein the control circuitry comprises circuitry to transmit a second data strobe signal via the shared strobe signaling interface to indicate times at which the memory control component is to sample the first and second read data bursts.

11. A method of operation within an integrated-circuit memory component having first and second command/address interfaces and first and second data interfaces, the method comprising:
receiving first and second memory access commands via the first and second command/address interfaces, respectively, the first memory access command indicating that a first write data burst is to be received via the first data interface and the second memory access command indicating that a second write data burst is to be received via the second data interface;
first receiving a first data strobe signal via a shared strobe signaling interface;
sampling the first write data burst within the first data interface at times indicated by the first data strobe signal; and
sampling the second write data burst within the second data interface at times indicated by the first data strobe signal.

12. The method of claim 11 wherein receiving the first and second memory access commands via the first and second command/address interfaces comprises receiving the first and second memory access commands at respective times that are offset from one another by a first interval and wherein sampling the first and second write data bursts within the first and second data interfaces comprises sampling the first and second write data bursts over respective second and third intervals that are offset from one another by the first interval.

13. The method of claim 11 wherein first and second command/address interfaces and first and second data interfaces are disposed on a first integrated circuit die that forms at least part of the integrated-circuit memory component.

14. The method of claim 11 wherein sampling the first write data burst at times indicated by the first data strobe signal comprises generating a first delayed data strobe signal having a first calibrated phase offset from the first data strobe signal and sampling the first write data burst in response to transitions of the first delayed data strobe signal.

15. The method of claim 14 wherein sampling the first write data burst in response to transitions of the first delayed data strobe signal comprises sampling the write data burst twice in succession for each cycle of the first delayed data strobe signal.

16. The method of claim 14 wherein sampling the second write data burst at times indicated by the first data strobe signal comprises generating a second delayed data strobe signal having a second calibrated phase offset from the first data strobe signal and sampling the second write data burst in response to transitions of the second delayed data strobe signal.

17. The method of claim 11 wherein the first data strobe signal comprises a plurality of active transitions that are preceded by a strobe preamble and succeeded by a strobe postamble, the active transitions continuing throughout an interval that exceeds a duration of the first write data burst and exceeds a duration of the second write data burst.

18. The method of claim 11 wherein the first data strobe signal comprises active transitions that are preceded by a strobe preamble and succeeded by a strobe postamble, and wherein a first subset of the active edges indicates times at which an initial portion of first write data burst is to be sampled and a second subset of the active edges indicates times at which a trailing portion of the second write data burst is to be sampled, the first subset including at least one active edge not included in the second subset and vice-versa.

19. The method of claim 11 wherein the first command/address interface and the first data interface are implemented in a first integrated circuit die within the integrated-circuit memory component and the second command/address interface and the second data interface are implemented in a second integrated circuit die within the integrated-circuit memory component and wherein receiving the first data strobe signal via the shared strobe signaling interface comprises receiving the first data strobe signal strobe signaling interface of the first integrated circuit die and conveying the first data strobe signal from the first integrated circuit die to the second integrated circuit die to enable sampling the second write data burst to be sampled within the second data interface at times indicated by the first strobe signal.

20. The method of claim 11 further comprising:
receiving third and fourth memory access commands via the first and second command/address interfaces, respectively, the third memory access command indicating that a first read data burst is to be transmitted to a memory control component via the first data interface and the fourth memory access command indicating that a second read data burst is to be transmitted to the memory control component via the second data interface; and
transmitting a second data strobe signal via the shared strobe signaling interface to indicate times at which the memory control component is to sample the first and second read data bursts.

21. An integrated-circuit memory component comprising:
first and second data interfaces;
first and second command/address interfaces to receive respective first and second memory access commands, the first memory access command indicating that a first write data burst is to be received via the first data interface and the second memory access command indicating that a second write data burst is to be received via the second data interface;
a shared data strobe interface to receive a first data strobe signal; and
means for enabling the first write data burst to be sampled within the first data interface at times indicated by the first data strobe signal, and for enabling the second write data burst to be sampled within the second data interface at times indicated by the first data strobe signal.
